(19) United States
(12) Patent Application Publication
(10) Pub. No.: US 2012/0227886 A1
(43) Pub. Date: Sep. 13, 2012

(54) Substrate Assembly Carrier Using Electrostatic Force

(75) Inventors: Yi-Li Hsiao, Hsin-Chu (TW); Chen-Hua Yu, Hsin-Chu (TW); Chung-Shi Liu, Hsin-Chu (TW); Chien Ling Hwang, Hsin-Chu (TW); Ying-Jui Huang, Taipei City (TW)

(73) Assignee: Taipei Semiconductor Manufacturing Company, Ltd., Hsin-Chu (TW)

(21) Appl. No.: 13/045,365

(22) Filed: Mar. 10, 2011

(51) Int. Cl. B32B 37/00; B23B 31/28; H01L 21/673; B23K 31/02

(52) U.S. Cl. 156/60; 228/256; 279/128; 29/559

(57) ABSTRACT

A portable electrostatic chuck carrier includes a holder having a dielectric top surface, and bipolar electrodes under the dielectric top surface. The bipolar electrodes includes positive electrodes and negative electrodes electrically insulated from the positive electrodes. The positive electrodes and the negative electrodes are allocated in an alternating pattern in a plane substantially parallel to the dielectric top surface.

### BACKGROUND

In the packaging of integrated circuits, dies may be packaged onto a laminate substrate, which includes metal connections that may route electrical signals between opposite sides of the laminate substrate. The dies may be bonded onto one side of a laminate substrate using flip chip bonding, and a reflow is performed to melt the solder bumps that interconnect the dies and the laminate substrate.

The laminate substrates use materials that can be easily laminated. These materials, however, are prone to the warpage caused by the elevated temperature used in the reflow of the solder bumps. The warpage may cause irregular joints and/or bump cracks, and lead to poor assembly yield. Conventionally, to reduce the warpage of a laminate substrate, jigs may be used to press the laminate substrate from both sides. The jigs may include a lower jig and an upper jig. The upper jig typically has a grid pattern with openings therein, and the laminate substrate is sandwiched between the lower jug and the upper jig. Portions of the laminate substrate are exposed through the openings in the upper jig. Dies are bonded to the laminate substrate through the openings. The jigs, however, also introduce problems. For example, the area of the laminate substrate occupied by the upper jig cannot be used for bonding dies, and hence is wasted. Furthermore, the conventional jigs need to have certain thicknesses for them to hold the laminate substrate in place. Accordingly, the upper jig may be in the way for accessing the dies and the laminate substrate from sides. This posts problems for certain process steps such as applying an underfill into the spaces between the dies and the laminate substrate because the underfill needs to be applied from the sides of the dies.

Furthermore, the using of jigs requires human intervention, and several jigs with different grid sizes may be needed in different packaging stages, such as bonding, flux cleaning, underfill applying, baking, testing, etc. This may cause the introduction of human errors into the processes. Accordingly, the process steps related to the usage of the laminate substrates become difficult to be automated.

### BRIEF DESCRIPTION OF THE DRAWINGS

For a more complete understanding of the embodiments, and the advantages thereof, reference is now made to the following descriptions taken in conjunction with the accompanying drawings, in which:

FIG. 1A illustrates a schematic view of an electrostatic chuck carrier, and a dielectric-containing package component chucked on the electrostatic chuck carrier through an electrostatic force;

FIG. 1B illustrates a top view of the bipolar electrodes in the electrostatic chuck carrier;

FIG. 1C illustrates a top view of localized charges accumulated at the bottom surface of the dielectric-containing package component;

FIG. 2 illustrates a circuit diagram of a charge station for charging the electrostatic chuck carrier;

FIG. 3 illustrates a circuit diagram of a discharge station for discharging the electrostatic chuck carrier;

FIG. 4 schematically illustrates a fully sealed electrostatic chuck carrier; and

FIGS. 5 through 7 schematically illustrate a packaging process, in which the electrostatic chuck carrier is used to chuck a laminate substrate.

### DETAILED DESCRIPTION OF ILLUSTRATIVE EMBODIMENTS

The making and using of the embodiments of the disclosure are discussed in detail below. It should be appreciated, however, that the embodiments provide many applicable inventive concepts that can be embodied in a wide variety of specific contexts. The specific embodiments discussed are merely illustrative, and do not limit the scope of the disclosure.

A novel electrostatic chuck carrier and the method of forming the same are provided in accordance with an embodiment. The variations and the operation of the embodiment are discussed. Throughout the various views and illustrative embodiments, like reference numbers are used to designate like elements.

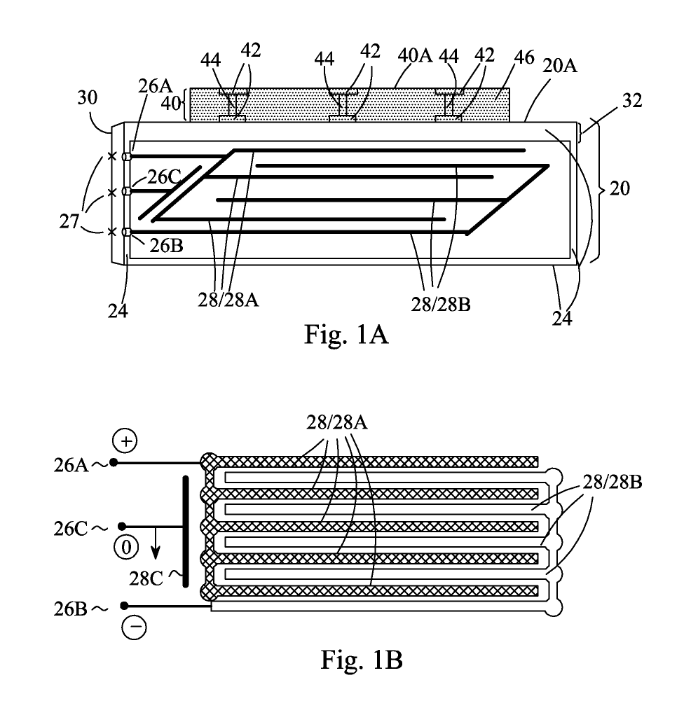

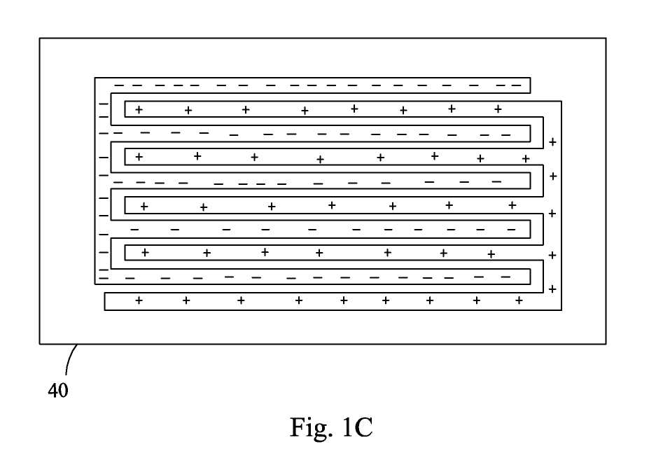

FIG. 1A illustrates a schematic view of electrostatic chuck carrier 20, which may be used as for chucking and transporting dielectric-containing component 40. Dielectric-containing component 40 may be chucked on electrostatic chuck carrier 20 by an electrostatic force. In an embodiment, electrostatic chuck carrier 20 is a portable electrostatic chuck carrier. In alternative embodiments, electrostatic chuck carrier 20 may be fixed on a platform of a production tool (not shown).

In an embodiment, dielectric-containing component 40 is a laminate substrate, which may comprise metal pads 42 on opposite sides of dielectric-containing component 40, and metal connections 44 connected to metal pads 42. Metal connections 44 route through dielectric material(s) 46 in dielectric-containing component 40. Although not illustrated, dielectric-containing component 40 may include solder bumps such as ball grid array (BGA) balls and micro solder bumps. In alternative embodiments, dielectric-containing component 40 may be other dielectric-containing components used in the integrated circuit manufacturing processes, such as an interposer or a carrier wafer, which may be a glass wafer.

Electrostatic chuck carrier 20 includes holder 24, which may substantially seal the internal components from external substances such as moisture and chemicals. Holder 24 may, or may not, include pin jacks 26 (denoted as 26A, 26B, and 26C), which are used for connecting electrical signals and power into electrostatic chuck carrier 20. When pin jacks 26 are formed, to prevent the moisture from penetrating into electrostatic chuck carrier 20 through pin jacks 26, elastic mask 30 may be used to cover the side of electrostatic chuck carrier 20 containing pin jacks 26. In alternative embodiments, elastic mask 30 may be formed as a seal ring. Elastic mask 30 may be formed of rubber, polymer, silicone elastomers, Fluorocarbon rubber (FKM, also sometimes known as fluoroelastomers), compressed asbestos fiber jointing, for example, although other materials may also be used. Elastic mask 30 may include small cuts 27 whose positions correspond to the positions of pin jacks 26. Cuts 27 may have, for example, a cross shape, wherein the material of elastic mask 30 is not removed from the cuts. Accordingly, when no external pins are inserted into pin jacks 26, cuts 27 are substantially sealed by the elastic material. When external pins are inserted into pin jacks 26, the external pins squeeze through cuts 27.

Electrostatic chuck carrier 20 may include a plurality of electrodes 28, which are aligned in a plane parallel to top surface 20A of electrostatic chuck carrier 20, wherein dielectric-containing component 40 is placed on, and may contact, top surface 20A. When electrodes 28 are charged, static charges are generated in dielectric-containing component 40, and hence dielectric-containing component 40 is chucked on top surface 20A. Dielectric layer 32 is formed as a part of electrostatic chuck carrier 20, and is located directly over electrodes 28. Top surface 20A may be the surface of dielectric layer 32. When dielectric-containing component 40 is chucked onto electrostatic chuck carrier 20, dielectric layer 32 separates and electrically insulates electrodes 28 from dielectric-containing component 40. Dielectric layer 32 may be formed of polymers and/or ceramics, and the thickness of dielectric layer 32 may be greater than about 20 μm, and may also be between about 200 μm and about 300 μm, for example.

FIG. 1B illustrates a top view of exemplary electrodes 28. In an embodiment, electrodes 28 include positive electrodes 28A and negative electrodes 28B. Accordingly, electrodes 28 are referred to as bipolar electrodes. In alternative embodiments, electrodes 28 are mono-polar, and may include either positive electrodes 28A or negative electrodes 28B, but not both. In addition, a ground electrode(s) 28C is provided for grounding. Positive electrodes 28A are electrically connected together, and are connected to pin jack 26A. Negative electrodes 28B are electrically connected together, and are connected to pin jack 26B, which is electrically insulated from pin jack 26A. Ground electrode 28C is connected to pin jack 26C. Positive electrodes 28A and negative electrodes 28B may be allocated in an alternating pattern. In an embodiment as shown in FIG. 1B, electrodes 28 are formed as parallel straight metal lines. In alternative embodiments (note shown), each of electrodes 28 may have any other applicable shapes such as a sine wave shape, a spiral shape, and the like.

When electrodes 28 are charged, positive electrodes 28A may be charged with positive charges, while negative electrodes may be charged with negative charges. Accordingly, charges are generated on the respective portions of dielectric-containing component 40 due to the redistribution of electrons. For example, FIG. 1C schematically illustrates a top view of a bottom surface portion of dielectric-containing component 40, with the bottom surface portion contacting surface 20A (FIG. 1A) of electrostatic chuck carrier 20. In the first surface portions (marked using “−” marks) that are directly over and vertically overlapping positive electrodes 28A, negative charges are accumulated, and hence the first surface portions are attracted to electrostatic chuck carrier 20. In the second surface portions (marked using “+” marks) directly over and vertically overlapping negative electrodes 28B, positive charges are accumulated, and hence the second surface portions are attracted to electrostatic chuck carrier 20 also. Since the charges are generated locally in dielectric-containing component 40, surface 40A (FIG. 1) of dielectric-containing component 40, which surface faces away from electrostatic chuck carrier 20, may be substantially neutralized and does not have a substantial positive charge accumulation or a substantial negative charge accumulation. As a result, in the various processes during which the integrated component 20/40 are processed, no accumulated charges on surface 40A can be undesirably removed. The de-chucking of dielectric-containing component 40 can thus be easily performed without the possibility of running into the problems that are caused by the polarization of dielectric-containing component 40.

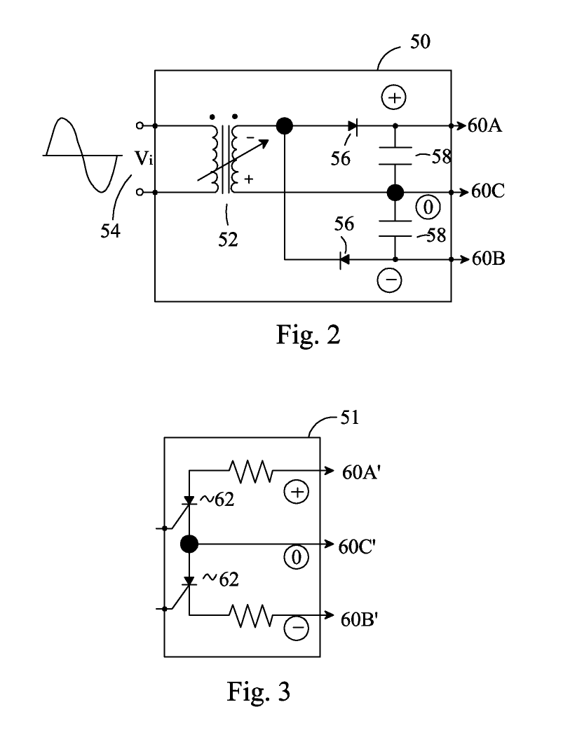

FIG. 2 illustrates exemplary charge station 50 for charging electrostatic chuck carrier 20. In an embodiment, charge station 50 includes transformer 52 for receiving AC power supply 54 that has AC voltage Vi. AC power supply 54 is rectified by, for example, diodes 56 and capacitors 58, so that pins 60A, 60B, and 60C act as a positive pin, a negative pin, and a ground pin, respectively. Pins 60A, 60B, and 60C fit pin jacks 26A, 26B, and 26C, respectively. To charge electrostatic chuck carrier 20, pins 60A, 60B, and 60C are inserted into pin jacks 26A (FIG. 1A, a positive pin jack), 26B (a negative pin jack), and 26C (a ground pin jack), respectively, and hence electrodes 28 are charged. After the charging, pins 60A, 60B, and 60C are removed from pin jacks 26A, 26B, and 26C, respectively.

FIG. 3 illustrates an exemplary discharge station 51, which includes, for example, diodes 62. To discharge electrostatic chuck carrier 20, pins 60A′, 60B′, and 60C′ are inserted to pin jacks 26A, 26B, and 26C of electrostatic chuck carrier 20, respectively, and hence electrodes 28 are discharged, and dielectric-containing component 40 is de-chucked from electrostatic chuck carrier 20. It is realized that charge station 50 and discharge station 51 may have various designs different than illustrated, which different designs are also in the scope of the present disclosure.

After each charge, which may last several seconds, for example, dielectric-containing component 40 may be chucked onto electrostatic chuck carrier 20 for several hours or several days without the need to recharge during this period of time. After this period of time, electrostatic chuck carrier 20 may be recharged.

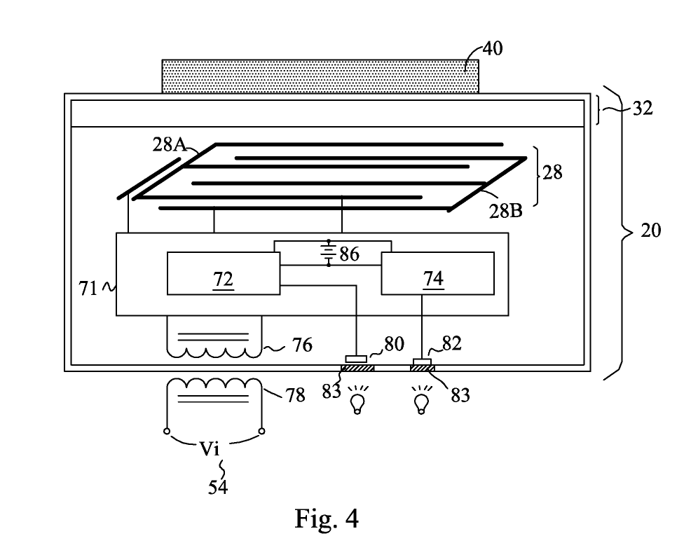

The electrostatic chuck carrier 20 as shown in FIG. 1A has pin jacks 26, and hence the internal components are not free from moisture, although the moisture penetration rate is low due to the use of seal mask 30. FIG. 4 illustrates fully sealed electrostatic chuck carrier 20. Electrostatic chuck carrier 20 may not have conductive outlets exposed to the external environment to receive power and/or electrical activation signals. In this embodiment, electrostatic chuck carrier 20 includes electrodes 28 (28A and/or 28B), and charge/discharge station 71. Charge/discharge station 71 further includes charge station 72 and discharge station 74, which charges and discharges electrodes 28, respectively. The electrical connections inside charge/discharge station 71 are not illustrated.

In the illustrated embodiment as shown in FIG. 4, inductor 76 acts as a wireless power receiver for receiving the power from inductor 78, which is external to electrostatic chuck carrier 20. Inductor 76 is so arranged so that it forms a transformer with inductor 78 when inductor 78 is placed close to inductor 76. Inductor 78 is connected to power supply source 54. Accordingly, power (electricity) may be transmitted into electrostatic chuck carrier 20 wirelessly through the transformer, which power is used to charge and discharge electrodes 28. The activation of the charging and discharging actions may be performed through signal receptors 80 and 82, which may be optical signal receptors or electromagnetic receptors. In the embodiments wherein receptors 80 and 82 are optical signal receptors, signal receptors 80 and 82 may be placed behind transparent windows 83, through which light signals may penetrate to reach signal receptors 80 and 82. For example, signal receptor 80 may receive an optical activation signal, which is used to activate charge station 72 to charge electrodes 28. Similarly, signal receptor 82 may receive an optical activation signal, which is transferred to activate discharge station 74 to discharge electrodes 28. Embedded rechargeable battery 86 may be disposed in electrostatic chuck carrier 20, and connected to inductor 76, charge station 72, and discharge station 74. Embedded rechargeable battery 86 may help operate charge station 72 and discharge station 74 upon the receiving of the charging and discharging activation signals. Embedded rechargeable battery 86 may also be recharged by the power received through inductor 76. With this design, electrostatic chuck carrier 20 does not need to have interfaces that are exposed to external environment for receiving the power and activation signals, and hence there is no moisture penetrating path for moisture to penetrate into electrostatic chuck carrier 20. As a result, the leakage currents and the leakage of charges inside electrostatic chuck carrier 20 are small, resulting in a longer charge holding time.

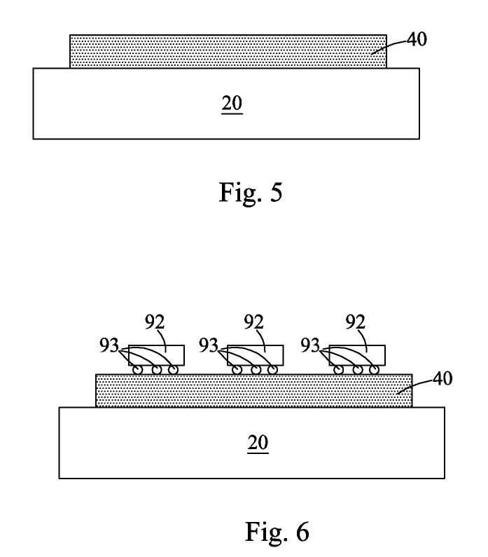

FIGS. 5 through 7 illustrate an exemplary integrated circuit manufacturing process in which electrostatic chuck carrier 20 is used. The internal structures of electrostatic chuck carrier 20 and dielectric-containing component 40 are not shown in FIGS. 5 through 7, and the details may be found in FIGS. 1A and 4, for example. Referring to FIG. 5, electrostatic chuck carrier 20 is provided. Dielectric-containing component 40, which may be a laminate substrate (and is referred to as laminate substrate 40 hereinafter) or another kind of package component such as an interposer, is loaded on electrostatic chuck carrier 20. Next, electrostatic chuck carrier 20 is charged to chuck laminate substrate 40, so that laminate substrate 40 is fixed on electrostatic chuck carrier 20.

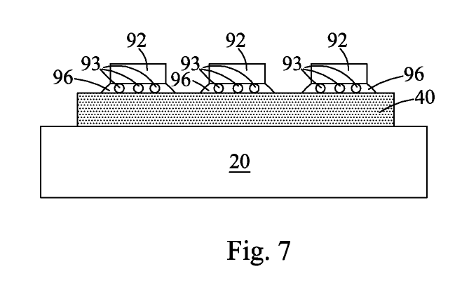

Next, as shown in FIG. 6, dies 92 are attached on laminate substrate 40 through solder bumps 93. After dies 92 are attached, the structure including dies 92, electrostatic chuck carrier 20, and laminate substrate 40 may go through a reflow process. Electrostatic chuck carrier 20 is formed using materials that may be placed under the reflow temperature without being damaged. After the reflow, a flux clean process may be performed to clean the flux used for the reflow process. Next, as shown in FIG. 7, underfill 96 is applied to the space between dies 92 and laminate substrate 40. The structure shown in FIG. 7 may then be sent into an oven for the curing of underfill 96. After all processes are finished, laminate substrate 40 may be de-chucked from electrostatic chuck carrier 20. During the entirety of the above-discussed process steps, laminate substrate 40 may be chucked on electrostatic chuck carrier 20 without being de-chucked. Alternatively, during any stage of the process steps as shown in FIGS. 5 through 7, laminate substrate 40 may be de-chucked and re-chucked. During the entire process as shown in FIGS. 5 through 7, component 20/40 acts as an integrated unit, and may be placed in a magazine (a substrate storage) for storing and transporting integrated component 20/40.

It is observed that in FIGS. 5 through 7, no jig needs to be placed over laminate substrate 40, while laminate substrate 40 is held onto electrostatic chuck carrier through the electrostatic force. Unlike in conventional schemes in which jigs are used, the force for holding dielectric-component 40 is applied globally, rather than only on grid lines that in contact with the jigs. The warpage prevention is thus more effective. With no upper jig being placed over laminate substrate 40, the above-discussed processes may be performed free from the problems caused by upper jigs that are on the way for various processes such as flux cleaning and underfill application. Furthermore, with no upper jigs needed, the area of laminate substrate 40 is not wasted.

In accordance with embodiments, a portable electrostatic chuck carrier includes a holder having a dielectric top surface, and bipolar electrodes under the dielectric top surface. The bipolar electrodes includes positive electrodes and negative electrodes electrically insulated from the positive electrodes. The positive electrodes and the negative electrodes are allocated in an alternating pattern in a plane substantially parallel to the dielectric top surface.

In accordance with other embodiments, an electrostatic chuck carrier is configured to chuck a dielectric component on a top surface of the electrostatic chuck carrier. The electrostatic chuck carrier includes a fully sealed holder/surface having a dielectric top surface; electrodes under the dielectric top surface and allocated in a plane substantially parallel to the dielectric top surface; and a wireless power receiver configured to receive power into the electrostatic chuck carrier wirelessly.

In accordance with yet other embodiments, a dielectric-containing component is loaded on an electrostatic chuck carrier. The electrostatic chuck carrier is charged to chuck the dielectric-containing component onto the electrostatic chuck carrier. The electrostatic chuck carrier and the dielectric-containing component chucked on the electrostatic chuck carrier may be transported as an integrated unit. The electrostatic chuck carrier may be discharged to de-chuck the dielectric-containing component from the electrostatic chuck carrier.

Although the embodiments and their advantages have been described in detail, it should be understood that various changes, substitutions and alterations can be made herein without departing from the spirit and scope of the embodiments as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized according to the disclosure. Accordingly, the appended claims are intended to include within their scope such processes, machines, manufacture, compositions of matter, means, methods, or steps. In addition, each claim constitutes a separate embodiment, and the combination of various claims and embodiments are within the scope of the disclosure.

What is claimed is:

1. A device comprising:
a portable electrostatic chuck carrier comprising:
a holder comprising a dielectric top surface; and
bipolar electrodes under the dielectric top surface, wherein the bipolar electrodes comprise positive electrodes and negative electrodes electrically insulated from the positive electrodes, and wherein the positive electrodes and the negative electrodes are allocated in an alternating pattern in a plane substantially parallel to the dielectric top surface.

2. The device of claim 1, wherein the portable electrostatic chuck carrier is fully sealed, and comprises an inductor for wirelessly receiving power into the portable electrostatic chuck carrier.

3. The device of claim 2, wherein the portable electrostatic chuck carrier further comprises signal receptors configured to receive external signals from outside the portable electrostatic chuck carrier, and wherein the portable electrostatic chuck carrier is configured to charge and discharge the bipolar electrodes in response to the external signals.

4. The device of claim 3, wherein the portable electrostatic chuck carrier further comprises an embedded rechargeable battery configured to activate the step of charging and discharging the bipolar electrodes in response to the external signals.

5. The device of claim 1, wherein the portable electrostatic chuck carrier further comprises pin jacks connected to the bipolar electrodes, and wherein the device further comprises:
a charge station configured to provide charges to the bipolar electrodes, wherein the charge station comprises pins fitting the pin jacks; and
a discharge station configured to discharge charges from the bipolar electrodes.

6. The device of claim 5, wherein the pin jacks comprise a positive pin jack connected to the positive electrodes, a negative pin jack connected to the negative electrodes, and a ground pin jack connected to an electrical ground.

7. A device comprising:
an electrostatic chuck carrier configured to chuck a dielectric component on a top surface of the electrostatic chuck carrier, wherein the electrostatic chuck carrier comprises:
a fully sealed holder comprising a dielectric top surface;
electrodes under the dielectric top surface and allocated in a plane substantially parallel to the dielectric top surface; and
a wireless power receiver configured to receive power into the electrostatic chuck carrier wirelessly.

8. The device of claim 7, wherein the electrodes comprise bipolar electrodes comprising positive electrodes and negative electrodes electrically insulated from positive electrodes, and wherein the positive electrodes and negative electrodes are allocated in an alternating pattern.

9. The device of claim 7, wherein the wireless power receiver comprises an inductor configured to form a transformer with an external inductor, and wherein the power is received through the transformer.

10. The device of claim 7, wherein the electrostatic chuck carrier further comprises a signal receptor configured to receive an external signal from outside the electrostatic chuck carrier, and wherein the electrostatic chuck carrier is configured to charge and discharge the electrodes in response to the external signal.

11. The device of claim 10, wherein the signal receptor comprises an optical signal receptor.

12. The device of claim 10, wherein the signal receptor comprises an electromagnetic signal receptor.

13. The device of claim 10, wherein the electrostatic chuck carrier further comprises an embedded rechargeable battery connected to the wireless power receiver.

14. A method comprising:
loading a dielectric-containing component on an electrostatic chuck carrier;
charging the electrostatic chuck carrier to chuck the dielectric-containing component onto the electrostatic chuck carrier;
transporting the electrostatic chuck carrier and the dielectric-containing component chucked on the electrostatic chuck carrier as an integrated unit; and
discharging the electrostatic chuck carrier to de-chuck the dielectric-containing component from the electrostatic chuck carrier.

15. The method of claim 14, wherein the dielectric-containing component comprises a laminate substrate, and wherein the method further comprises, at a time the dielectric-containing component is chucked on the electrostatic chuck carrier, bonding a die onto the laminate substrate.

16. The method of claim 15 further comprising reflowing solder bumps between the die and the laminate substrate, wherein during the step of reflowing, the dielectric-containing component is chucked onto the electrostatic chuck carrier.

17. The method of claim 14, wherein the step of charging the electrostatic chuck carrier comprises:
inserting pins into the electrostatic chuck carrier; and
providing charges to electrodes in the electrostatic chuck carrier through the pins.

18. The method of claim 14, wherein the step of charging the electrostatic chuck carrier comprises wirelessly providing power into the electrostatic chuck carrier to charge electrodes in the electrostatic chuck carrier.

19. The method of claim 18 further comprising providing a signal into the electrostatic chuck carrier to activate the step of charging, wherein the signal is received through a receiver selected from the group consisting essentially of an electromagnetic signal receptor and an optical signal receptor.

20. The method of claim 18 further comprising wirelessly providing power and an activation signal into the electrostatic chuck carrier to discharge electrodes in the electrostatic chuck carrier.
